(19) United States
(12) Patent Application Publication
(10) Pub. No.: US 2012/0112541 A1
(43) Pub. Date: May 10, 2012

(54) HIGH-CONCENTRATION PHOTOVOLTAIC GENERATING MODULE

(75) Inventor: Gian Pietro Beghelli, Monteveglio (Bologna) (IT)

(73) Assignee: BEGHELLI S.p.A., Monteveglio (BO) (IT)

(21) Appl. No.: 13/261,039

(22) PCT Filed: May 27, 2010
(86) PCT No.: PCT/IT2010/000233

§ 371 Date: Jan. 4, 2012

(30) Foreign Application Priority Data
May 28, 2009 (IT) VI2009A000122

(51) Int. Cl. H01L 31/052; H02J 1/00

(52) U.S. Cl. 307/29; 307/71; 136/246; 307/82

(57) ABSTRACT

A structural module (11) for the high-concentration single-reflection photovoltaic generation, comprising a plurality of devices concentration of solar radiation (RS), which include relative parabolic reflectors (13) mounted on a base support (15), placed within the module (11), a transparent front surface (14), through which is the solar radiation (RS) is transmitted, and a plurality of photovoltaic receivers (16), mounted within the module (11) and series-connected each other,

wherein the photovoltaic receivers (16) are fixed on elongated elements (10, 12), made of conductive material and suitable to dissipate heat, which accommodate a photovoltaic cell (CS) and are placed outside or inside the structural module (11).

The present invention relates generally to a high-concentration photovoltaic generating module.

More particularly, the invention relates to a concentrator of sunlight, its photovoltaic receiver and the high-concentration photovoltaic module, obtained with the use of such concentrator and receiver devices.

It is known that concentration photovoltaic generating system typically includes a series of cells (so-called photovoltaic cells) which convert input sunlight into electrical energy, and at least one concentrator which allows to concentrate the sunlight on said cells.

The concentrator device may be of reflective surfaces (mirrors) or lenses type.

Depending on the geometry created by the reflecting surfaces it is possible to vary the achievable light concentration factor.

More factors of solar concentration can be achieved using concentrators with curved reflecting surfaces, such as parabolic concentrators, which present sections formed by branches of parabola along the direction of incidence of the sunbeams.

However, even in this case, the solar concentration factor is still low.

Other concentrators with reflecting surfaces of the known type make use of paraboloids, which are able to concentrate a beam of sunlight onto a small area, substantially corresponding to the focus of the paraboloid, where one or more matrixes which house a plurality of photovoltaic cells are arranged.

These systems present a relatively high concentration factor, however good operation of such devices is achieved only if the beam of sunlight presents a high degree of uniformity when it hits the cell, feature which can be obtained using an additional concentrator (for instance with parabolic geometry), placed in the focal area, in front of the photovoltaic cells.

In any case, the single-reflection concentrators with reflecting surfaces present are problematic for building the heat dissipation system, since the passive dissipation system must be allocated onto the surface crossed by the sunlight before striking the reflecting mirror.

For this reason single-reflection concentrators typically use active dissipating systems, in order to avoid overheating of the photovoltaic cells. Concentrators of the lenses type normally include a series of optical lenses units, each of which suitable to directly receive the sunlight and concentrate it on the relative photovoltaic cell.

The concentration factor which can be obtained using these systems is relatively high and the heat produced by the concentration of the sunlight can be dissipated in a passive way, however it is difficult and expensive to build lenses with durable materials such as glass and lenses made of methacrylate are usually used, whose durability is still nowadays under discussion; it results in any case a fairly rapid deterioration of the materials used.

Purpose of the present invention is therefore to overcome the abovementioned drawbacks and, especially, to create a high-concentration photovoltaic generating module which allows to achieve high efficiency of the optical system, dimensions and number of photovoltaic cells used being equal, compared to the prior art.

Other purpose of the present invention is to provide a high-concentration photovoltaic generating module which allows to get a better heat dissipation which develops inside the module, with respect to the known art.

Another purpose of the invention is to provide a generator and a photovoltaic receiving device suitable to be used in high-concentration modules for the photovoltaic generation.

Further purpose of the invention is to concrete a high-concentration photovoltaic generating module which has a significant competitive advantage in terms of simplicity and swiftness of installation and high reduction operating costs, by virtue of the module and optical system efficiencies produced, compared to conventional constructive solutions.

These and other purposes are achieved by a high-concentration photovoltaic generating module according to the claim 1 enclosed; other technical features of detail are set forth in the subsequent claims.

In advantageous way, efficiencies of the photovoltaic generation module over 21% for overall dimensions of 900×900 mm (with about 150 mm in thickness or height) are achieved, using a matrix of 64 elements of 110×110 mm each.

The minimum efficient obtained of the optical system is about 70% and a power of 3 kW is produced by carrying out a structure of 20 modules having overall dimensions of 4.600×3.900 mm.

Additional features and advantages of a high-concentration photovoltaic generating module, according to the present invention, will be more apparent from the following description, related to an illustrative and preferred, but not limiting, embodiments and the attached drawings, related to preferred, but not limiting, embodiments as well in which:

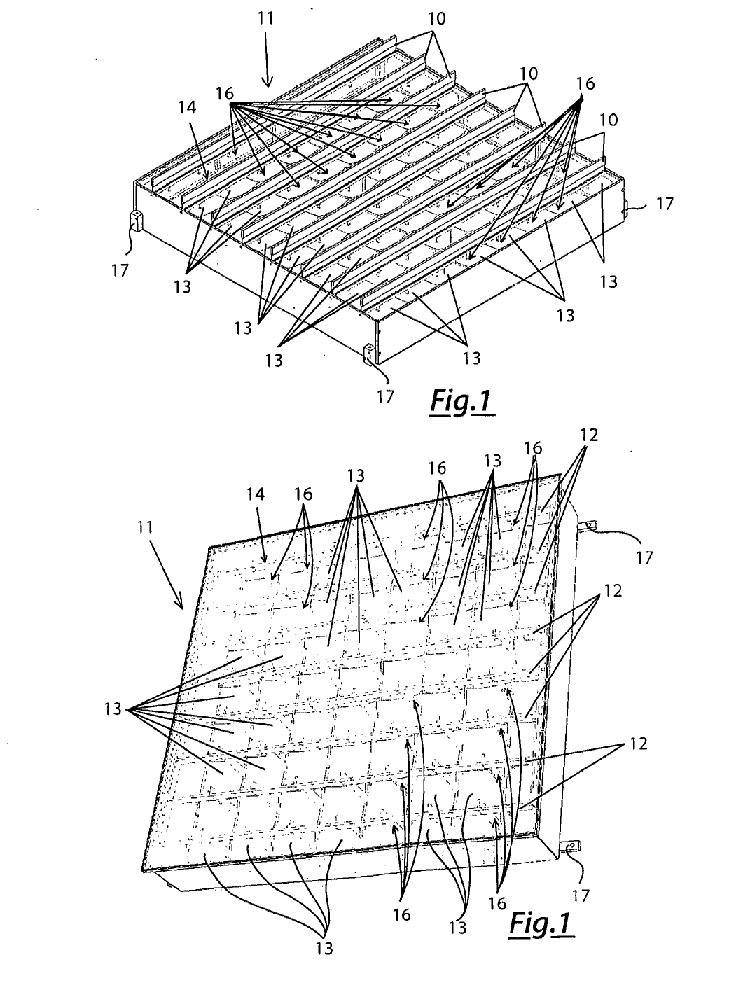

FIG. 1 shows a perspective view of a first embodiment of a high-concentration photovoltaic generating module, according to the present invention;

FIG. 2 shows a perspective view of a further embodiment of a high concentration photovoltaic generating module, according to the present invention;

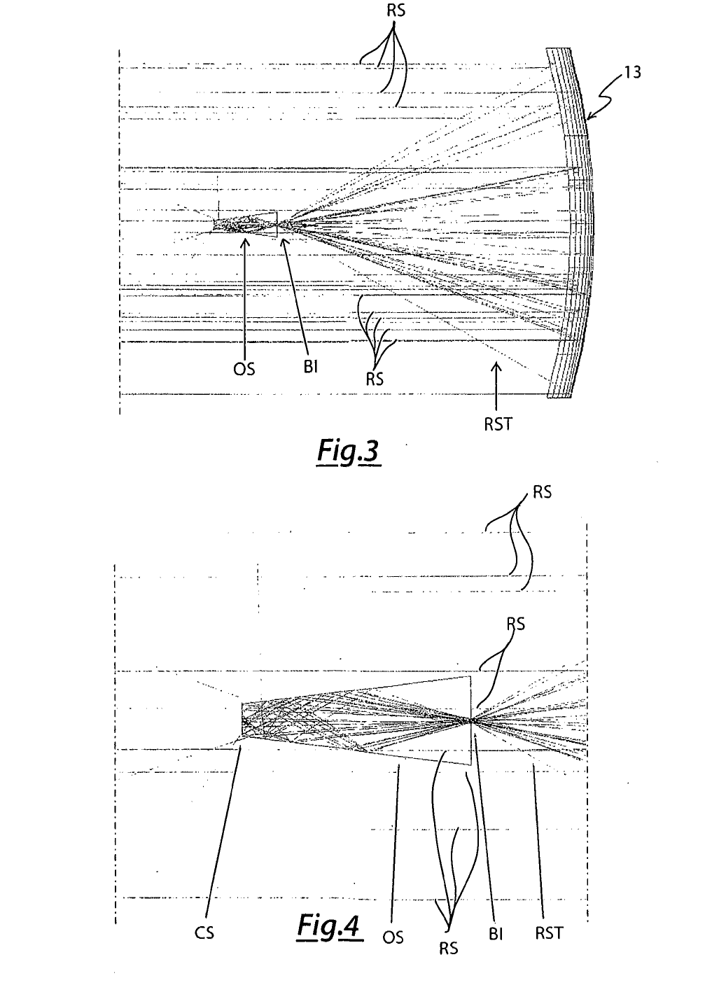

FIG. 3 shows a schematic view of a concentrator, used in the high-concentration photovoltaic generating module, according to the present invention, and illustrated with its own operation principle and the respective optical light beams, obtained with a “ray-tracing” technique simulator;

FIG. 4 shows an enlarged detail of FIG. 3, according to the present invention;

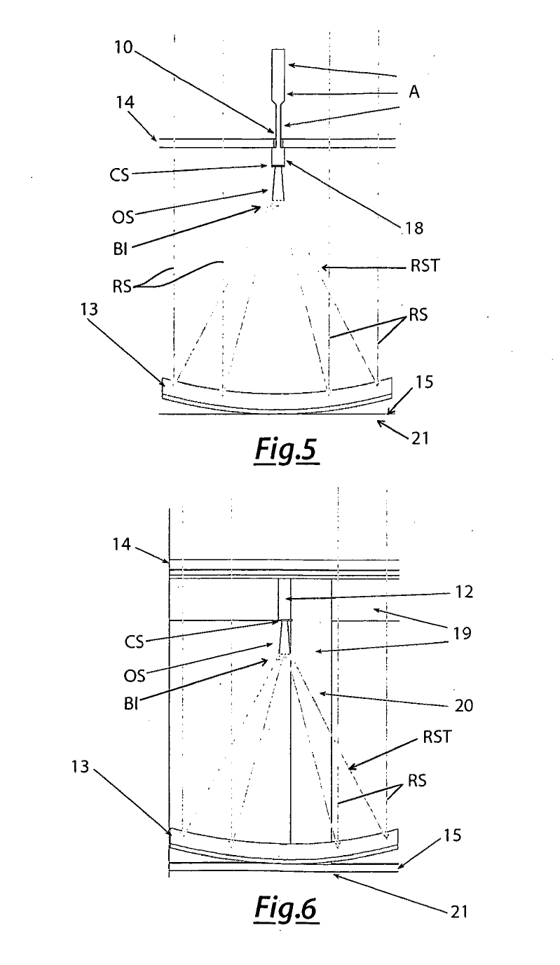

FIG. 5 shows a scheme of optical concentration obtained for the photovoltaic generating module of FIG. 1, according to the present invention;

FIG. 6 shows a scheme of optical concentration obtained for the photovoltaic generating module of FIG. 2, according to the present invention;

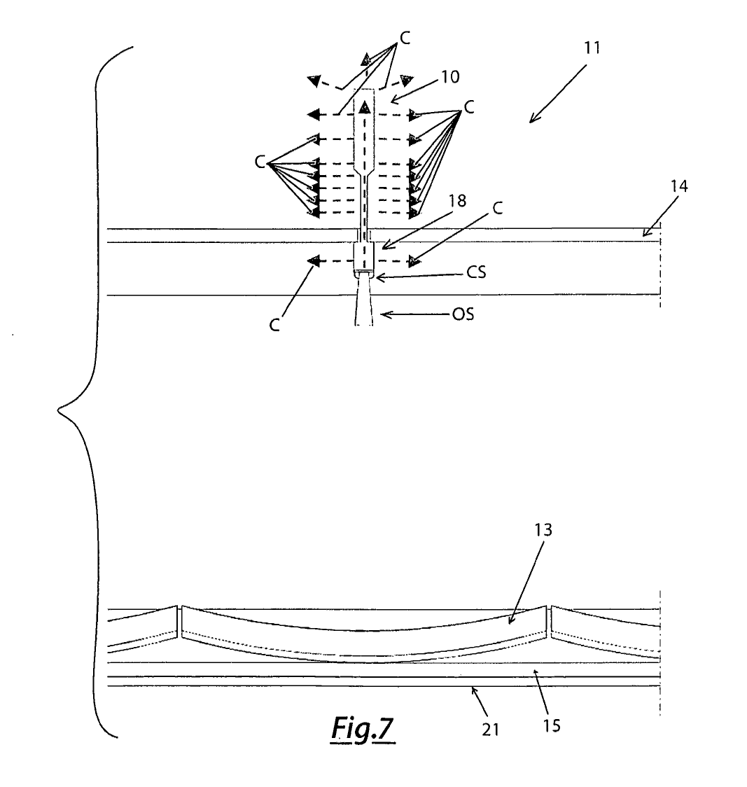

FIG. 7 is a schematic and partial section view of the high-concentration photovoltaic generating module of FIG. 1, according to the invention, highlighting the heat flows;

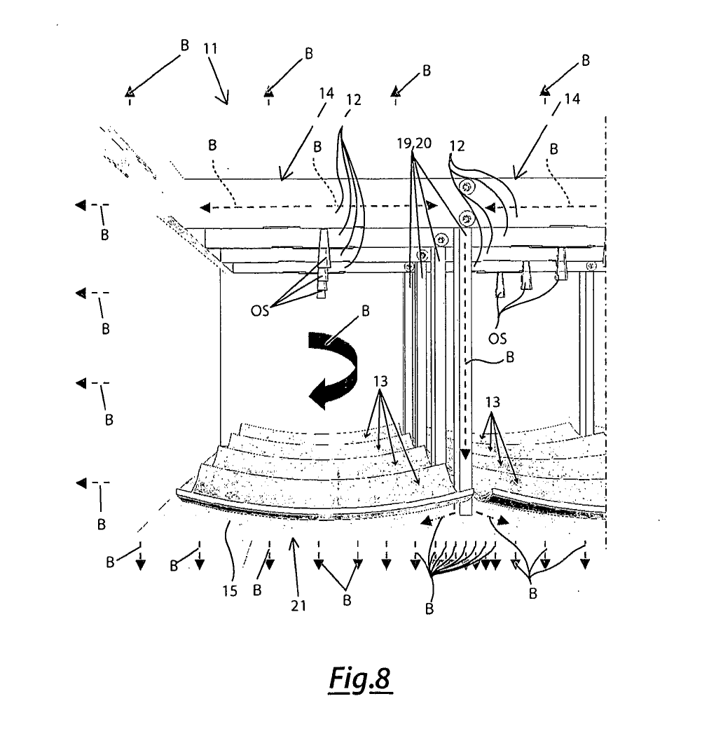

FIG. 8 is a schematic and partial view of the inside of the high-concentration photovoltaic generating of FIG. 2, according to the present invention, pointing out the heat flows towards the outside;

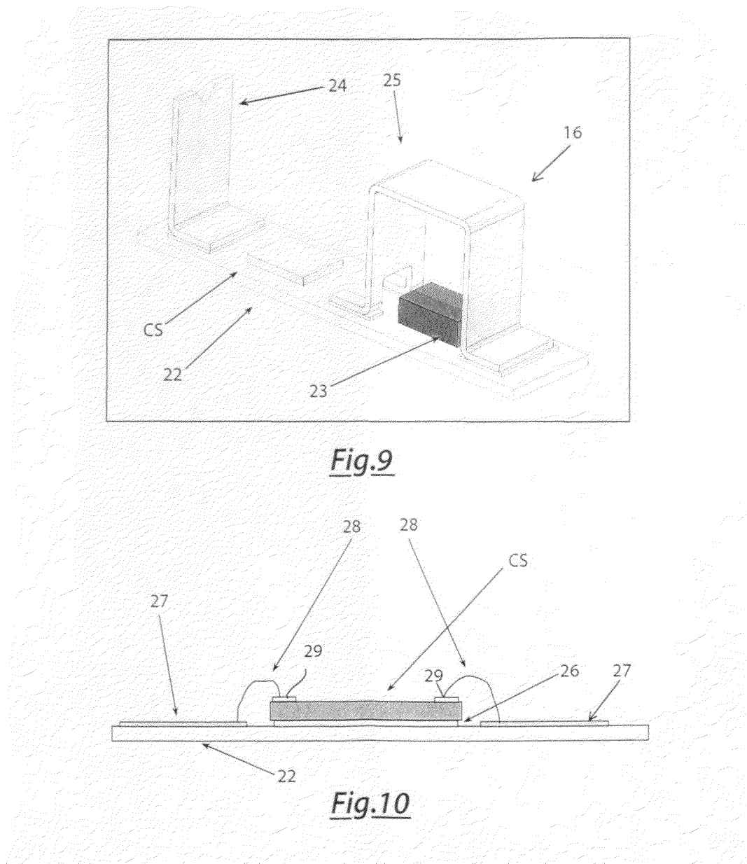

FIG. 9 is a schematic perspective view of a photovoltaic receiver used in the high-concentration photovoltaic generating module, according to the present invention;

FIG. 10 is a schematic and partial section of a photovoltaic cell of the high-concentration module mounted on the receiver of FIG. 9, according to the present invention;

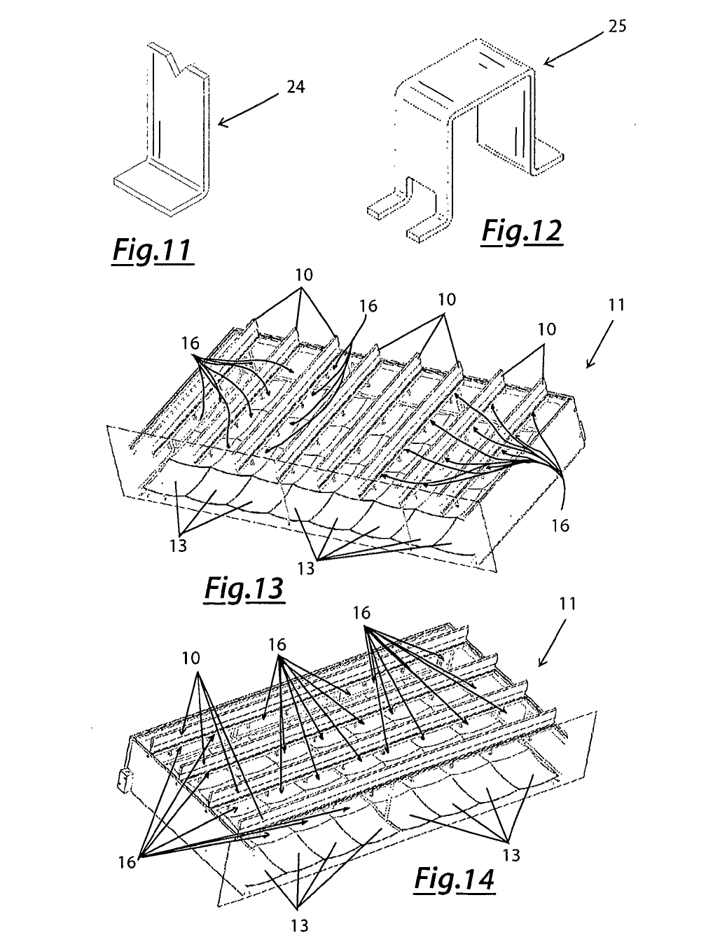

FIG. 11 shows a perspective view of a first detail of FIG. 9, according to the invention;

FIG. 12 shows a perspective view of a second detail of FIG. 9, according to the present invention;

FIGS. 13 and 14 show two schematic and partial sections of the high-concentration photovoltaic generating module of FIG. 1, according to the present invention;

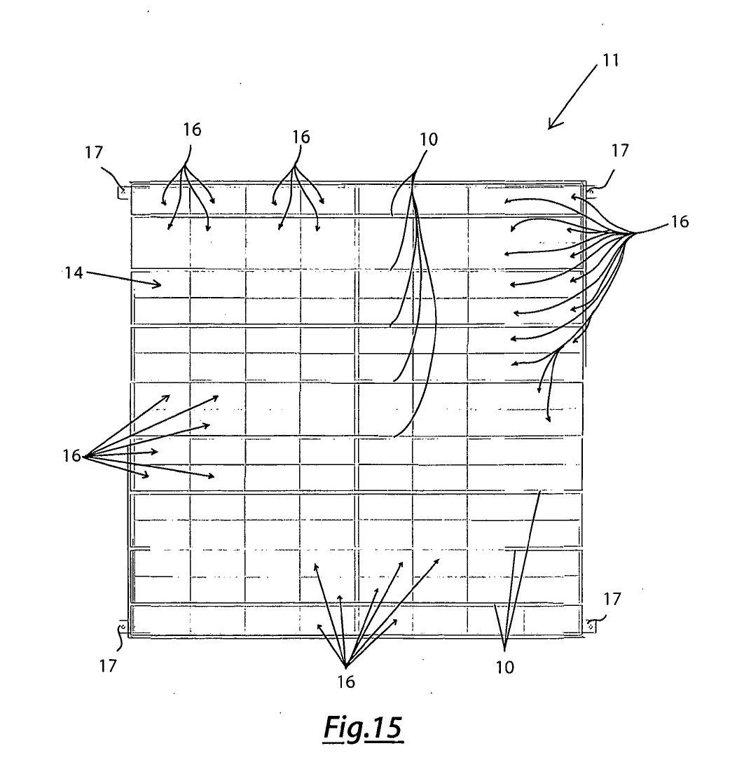

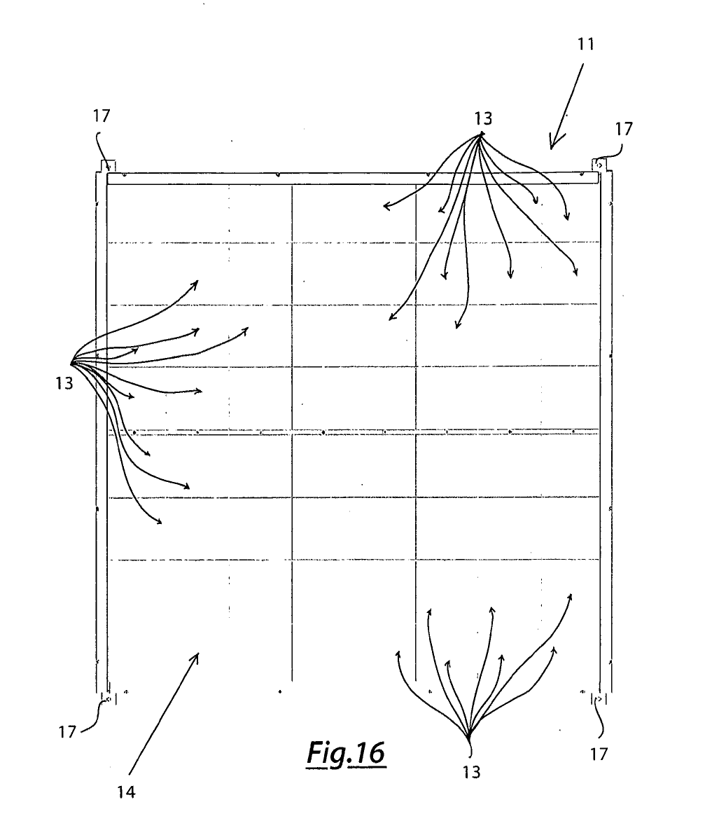

FIG. 15 shows a front view of the high-concentration photovoltaic generating module of FIG. 1, according to the invention;

FIG. 16 shows a rear view of the high-concentration photovoltaic generating module of FIG. 1, according to the present invention;

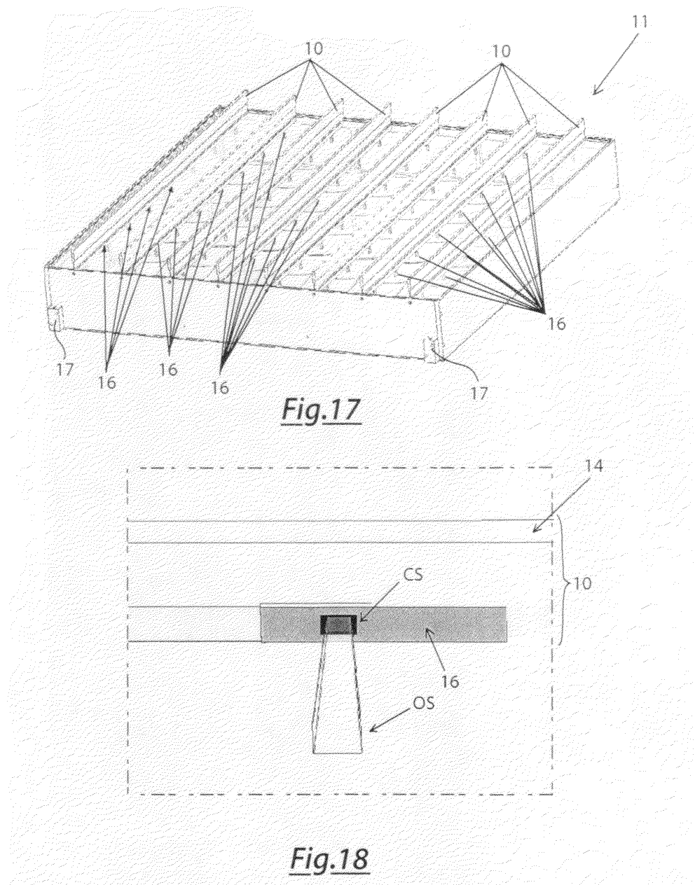

FIG. 17 is a top perspective view of the high-concentration photovoltaic generating module of FIG. 1, according to the present invention;

FIG. 18 is a schematic view of the photovoltaic receiver mounted on the dissipator inside the photovoltaic generating module of FIG. 1, according to the present invention;

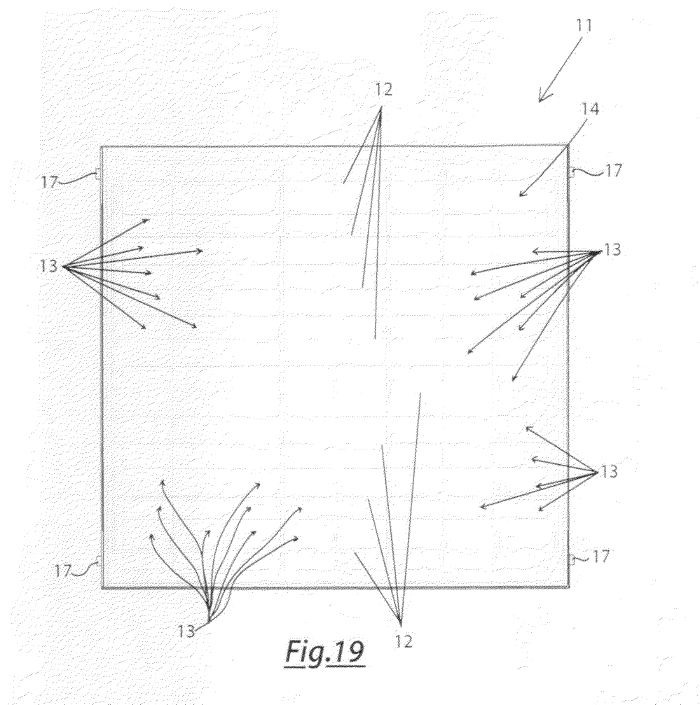

FIG. 19 is a front view of the high-concentration photovoltaic generating module of FIG. 2, according to the present invention;

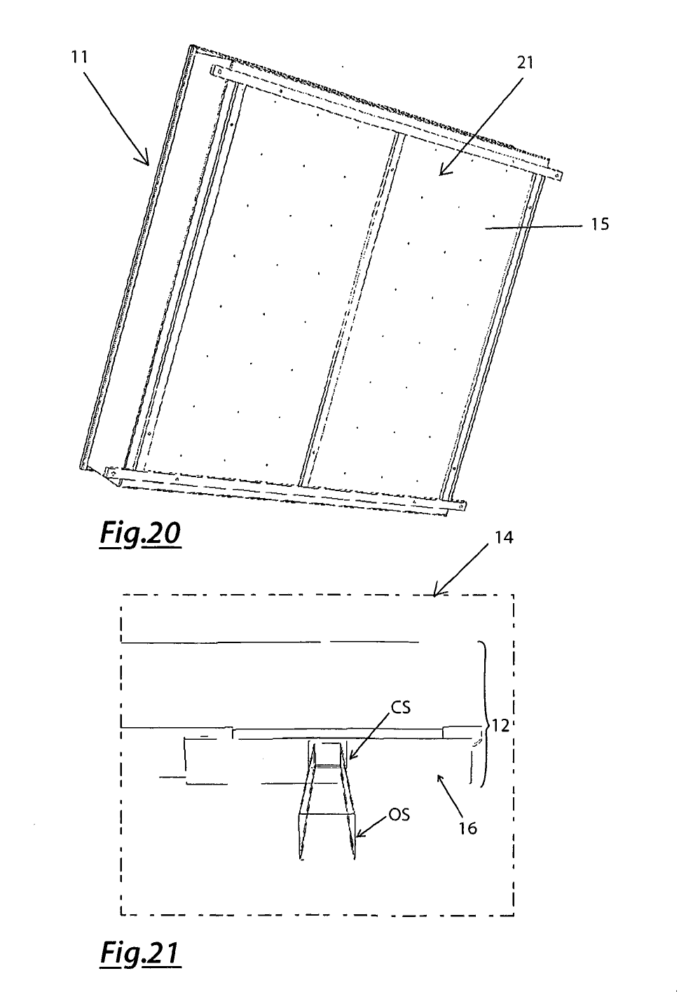

FIG. 20 is a rear perspective view of the high-concentration photovoltaic generating module of FIG. 2, according to the present invention;

FIG. 21 is a schematic view of the photovoltaic receiver mounted on the dissipator inside the photovoltaic generating module of FIG. 2, according to the present invention;

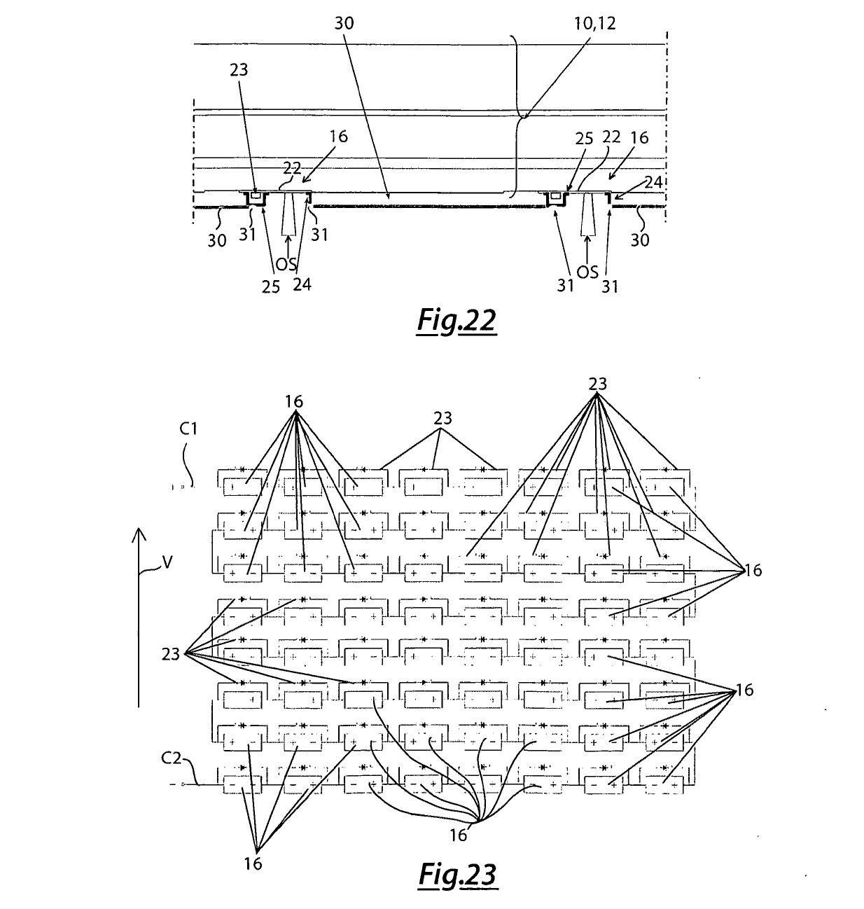

FIG. 22 shows a wiring diagram between the receivers of the high-concentration photovoltaic generating module, according to the present invention;

FIG. 23 shows a wiring diagram of the photovoltaic cells present in the high-concentration photovoltaic generating module, according to the invention;

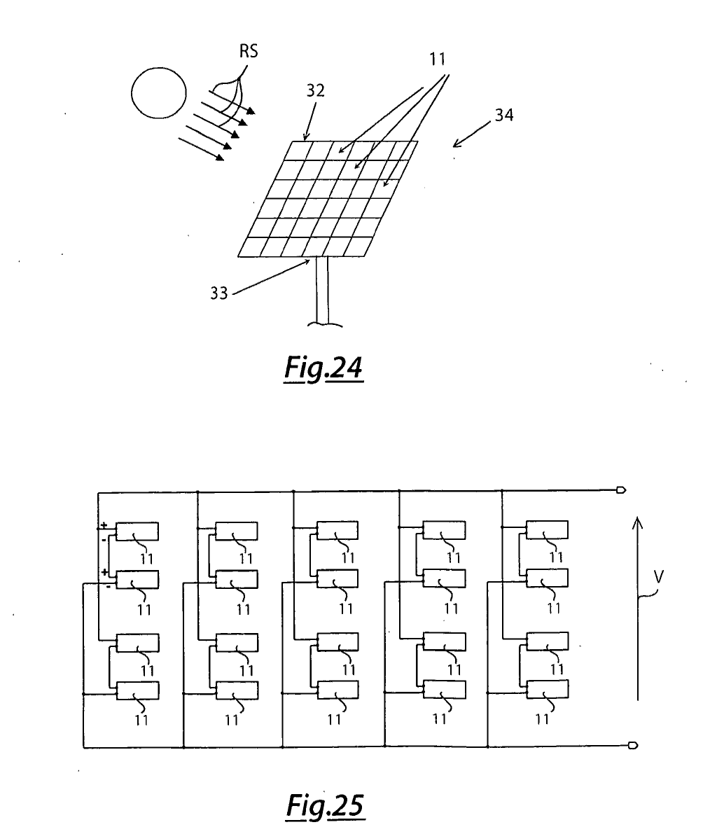

FIG. 24 shows a schematic implementation of a photovoltaic generator staring from a high-concentration photovoltaic generating module, according to the present invention;

FIG. 25 shows a wiring diagram of the high-concentration photovoltaic generating modules, according to the present invention, arranged inside a 3 kW photovoltaic generator;

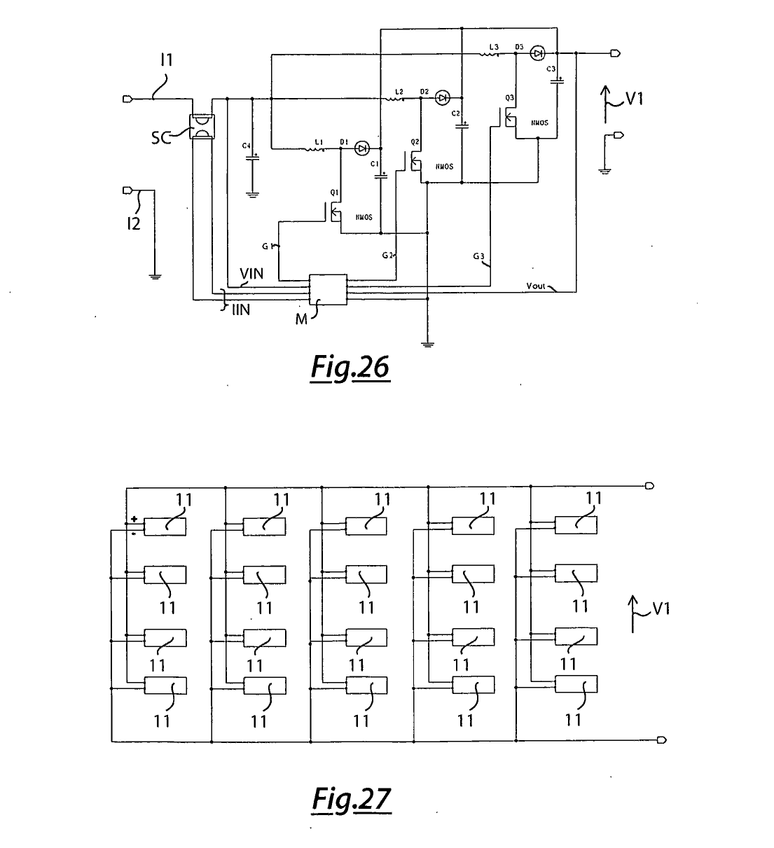

FIG. 26 shows a circuit diagram of an electronic module converter;

FIG. 27 shows a wiring diagram of the photovoltaic generating modules, complete with the relative electronic converter of FIG. 26 on board, inside a 3 kW photovoltaic generator;

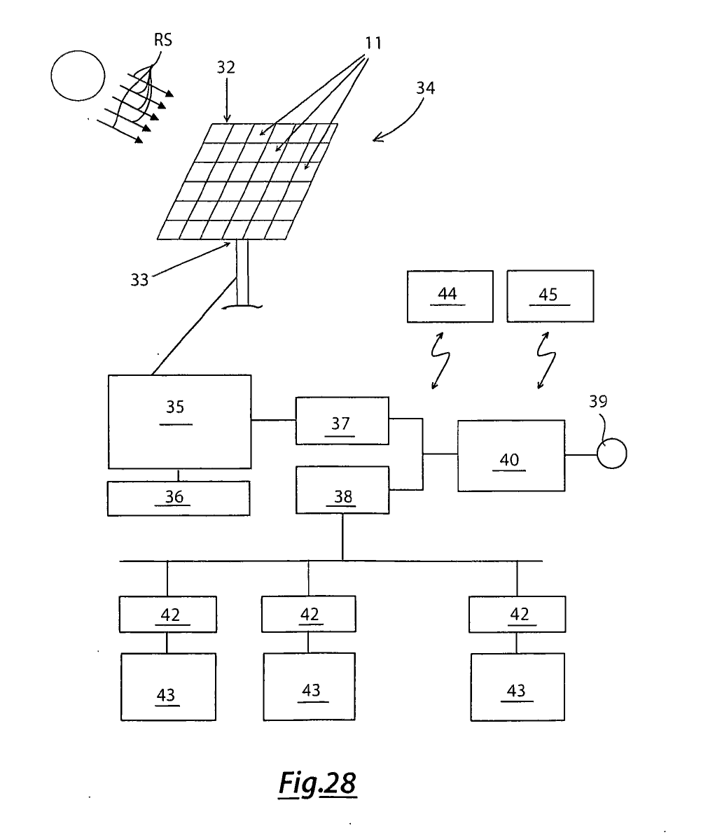

FIG. 28 shows a block diagram of a photovoltaic generating system, carried out through high-concentration photovoltaic generating modules, according to the present invention, and integral with an existing home automation system for the energy management in residential-commercial circle.

With reference to the figures mentioned, the high-concentration photovoltaic generating module, according to the present invention, is generally indicated with 11 and can be implemented in two different embodiments, which are shown respectively in the appended FIGS. 1 and 2 and which provide the use, respectively, of elongated elements 10 of heat dissipation arranged outside the module 11 and elongated elements 12 of heat dissipation arranged inside the module 11.

Whether in the embodiment of FIG. 1 or that one of FIG. 2, the photovoltaic module 11 includes:
a plurality of solar radiation concentrating devices, which include respective parabolic reflectors 13 mounted inside and on the lower plane of the module 11;
a transparent front surface 14, through which the solar radiation is transmitted;
a lower or bottom base 15 for supporting the reflectors 13,
a plurality of photovoltaic receivers 16, mounted inside the module 11 on the elongated elements 10, 12 of heat dissipation and
appropriate brackets 17 for fixing the modules 11 each other and/or to a complete system of photovoltaic generation.

With specific reference to FIGS. 3-6, each concentrator of solar radiation includes the parabolic reflector 13 which concentrates the solar radiation RS on the inlet BI of a secondary homogenization optics OS.

In practice, the incident rays of the solar radiation RS cross the transparent protection surface 14 of the module 11 and reflect on the parabolic reflector 13 in order to concentrate, as incoming light flow RST, on the focus of the latter, located at the inlet BI of the secondary optics OS.

The secondary optics OS consists in practice of a truncated pyramid, whose side walls reflect, thanks to the phenomenon of the total reflection, the rays of sunlight coming in the inlet BI.

In addition, the side walls have inclinations specifically designed so that the truncated pyramid acts as homogenizer of the incoming light flow RST. In this way, the underneath photovoltaic cell CS, located at the inner side 18 of each elongated element 10, 12 of heat dissipation, is illuminated by a homogeneous light flow, without peaks of distribution of the solar energy incident on the aforesaid cell CS.

Another purpose of the secondary optics OS is to increase the acceptance angle of the optical system, i.e. the maximum allowable misalignment angle of the concentrator relative to the sunlight rays direction.

Using the secondary optics OS, the maximum allowable misalignment angle of the concentrator is approximately 1-2°.

The incoming solar radiation RS is thus overall concentrated of a geometric concentration factor equal to 1.260, as ratio between the area of the entry surface of the parabolic reflector 13 projected onto the transparent surface 14 and the area of the photovoltaic cell CS (geometric concentration is indeed equal to (110×110 mm)/(3.1×3.1 mm)).

Each parabolic reflector 13 is made with at least one of the following technology:
1) aluminium sheet drawn and mirror polished on the concave surface;
2) injection moulded plastic (polycarbonate or equivalent material) obtained from mirror polished mould and metalled with aluminium deposited under vacuum by evaporation or sputtering;
3) mirror glass and metalled with aluminium deposited under vacuum by evaporation or sputtering.

The truncated pyramid which composed the secondary optics OS is made of glass or quartz, these being the only transparent materials (with high optical transmittance in the radiation band of interest, included between about 300 and 2.000 nm) able to reliably operate for many years, although subject to a high intensity of the solar radiation RST crossing them.

The solar or photovoltaic cell CS used is of the multi-junction type, made of materials of the III-V series (germanium, gallium, arsenic, indium), and is preferably of the triple junction type, characterized by a conversion efficiency of about 35% at the concentration of 1.000 suns, equal to 1.000.000 W/m² (equivalent to 100 W/cm²).

The efficiency of the optical system as a whole, which suffers crossing losses of the protection glass 14, losses of reflection on the paraboloid 13, crossing losses of the secondary optics OS and losses of dimming (due to the shadow caused by each elongated strip 10, 12 of heat dissipation, on which the solar or photovoltaic cells CS are mounted), is normally included between 67% and 80% and may exceed 88% using, in particular, silver reflectors.

The following table globally summarizes the minimum and typical efficiency values of the optical system identified, respectively, without any treatment of the indicated surfaces (transparent surface or protection glass, parabolic reflector, secondary optics), with antireflection treatments and/or special covering procedures of the aforesaid surfaces.

| | | Efficiency with | Efficiency with |
|---|---|---|---|
| | | glasses treated | glasses treated |
| | Minimum | with | with anti- |
| | efficiency without | antireflection and | reflection and |
| | antireflection | special | silver-plated |
| Optical element | treatments | aluminizing | mirror |
| Protection | 92% | 96% | 96% |
| glass | | | |
| Parabolic mirror | 85% | 89% | 95% |
| Secondary | 90% | 94% | 94% |
| optics | | | |
| Loss of | 5% | 5% | 5% |
| dimming | | | |
| Global optical | 67% | 75% | 82% |
| efficiency | | | |

The maximum solar radiation incident on the photovoltaic module 11 is equal to 1000 W/m² and therefore produces on the transparent surface 14, as projection of the parabolic reflector 13, a power equal to (1.000×0.11×0.11) W=12.10 W.

Given the efficiency of the optical part, the power incident on the cell CS is included between 8.11 W (12.10×0.67) and 9.92 W (12.10×0.82), while, given the electrical efficiency of the cell CS, the power incident on the CS cell, which is transformed into heat and therefore it is necessary to dissipate, is included between 2.84 W (8.11×0.35) and 3.47 W (9.92×0.35).

In the embodiment represented in FIGS. 1 and 5 (i.e. with the elongated elements 10 of heat dissipation placed outside the module 11), heat to be dissipated propagates outwards crossing the elongated element 10, preferably made of aluminium; thanks to this technical solution, the size of each elongated dissipating element 10 is minimal, since it is an elongated element of about 6×55 mm, which is able to keep the operating temperature of the cell CS at values lower than 80° C.

The optimal operation of each elongated heat dissipating element 10 is due to the fact that most of the surface (the part labelled with A in FIG. 5 enclosed) of the aforesaid elongated heat dissipating element 10 faces directly to the outside of the module 11; moreover, the small sizes of each aluminium elongated heat dissipating element 10 allow to keep the total cost at minimum.

Even the embodiment shown in the attached FIG. 6 (with the heat dissipation elongated elements 12 placed inside the module 11) presents a good thermal operation, but needs a much greater amount of aluminium, since it requires a reticular structure, made inside the module 11 and consisting of inner portions 19 of each elongated heat dissipating element 12 and a grid of aluminium flow tubes 20, connected at low thermal resistance with the elongated elements 12, on which the CS cells are mounted.

In this way, indeed, it is possible to increase the surface of aluminium present inside the module 11, in order to facilitate heat exchange with the air inside the same module 11, and convey the heat with as low thermal resistance as possible towards the lower base 15, preferably made of aluminium and thermally connected with the inner part 19 of each elongated heat dissipating element 12, in order to allow the convey of heat to the air present outside the module 11 through the rear surface 21 of the base 15, facing the outside, which allows heat exchange.

In particular, in the attached FIG. 7, the thermal flows are shown, indicated by the arrows C, which are established in a photovoltaic module 11 with elongated heat dissipating elements 10 arranged outside the module 11 of FIG. 1, while in the attached FIG. 8 heat flows are shown, indicated by the arrows B, which are established inside a photovoltaic module 11 with the elongated heat dissipating elements 12 arranged inside the module 11 of FIG. 2.

Both the embodiments (with dissipating elongated elements 10, 12 placed respectively outside and inside the module 11) allow to effectively dissipate the heat produced by the solar cells CS and make it possible to build a single reflection concentration photovoltaic module 11 with negligible losses of dimming (due to the support structure of the cells CS). Heat dissipation is made possible with a passive solution, based on the bars 19 and/or aluminium flow tubes 20, without having to use forced circulation cooling fluids and/or other complex and expensive solutions.

The advantage of the single-reflection embodiment is also due to the high optical efficiency which can be reached, just attenuated by a very small percentage (5%) of losses due to shading phenomenon, in turn caused by the presence of the support and dissipation structure of the cells CS.

The result is an extremely compact concentration, easy to produce and low cost module.

The embodiment with elongated dissipating elements 12 inside the module 11, while needing a larger amount of aluminium than the embodiment with elongated heat dissipating elements 10 outside the module 11, advantageously presents a single upper smooth and transparent surface 14 (in practice a single panel made of glass), without the presence of projections.

With particular reference to the attached FIGS. 9-12, each photovoltaic receiver 16 (shown in the appended FIG. 9 without the secondary optics OS for the sake of greater clarity) of the module 11, consists of:
an alumina plate 22, which presents high thermal conductivity and high electrical insulation;
a solar or photovoltaic cell CS;
a bypass diode 23;
two shaped elements 24, 25, made of brass or tinned copper, on which the copper wires, necessary for interconnecting each other the various receivers of the photovoltaic module 11 and extracting the photovoltaic current from receivers, are welded.

The shaped element 25, arranged above the bypass diode 23, has also the purpose to protect the silicium diode 23 (arranged inside a plastic envelope of dark colour) from the solar radiation RST incident and concentrated by the parabolic reflector 13, in case the module 11 is misaligned by a few degrees with respect to the sun; in such a case, indeed, the concentrated solar beam RST could affect the surface of epoxy resin of the diode 23 damaging it for the excessive heat caused by the concentrated beam RST.

The embodiment shown in the attached FIG. 9 allows also to achieve with a simple metallic element 25 the two functions of electrical connection and protection from the concentrated solar beam RST.

The alumina plate 22 presents silver silk-screen printed conductive tracks 27, produced with the technology of thick film on their own surfaces, so as to establish electrical connections between the solar cell CS, the diode 23 and the shaped elements 24, 25.

Furthermore, the solar cell CS is mounted on the plate 22 by welding the bottom surface of the cell CS (which constitutes one of two electrodes of the cell itself) on the plate 22, by means of a tin or thermally and electrically conductive polymer welding 26, and connecting through the bonding wires 28 the other electrode 29 of the photovoltaic or solar cell CS with the conductive tracks 27 of the plate 22 (as shown in detail in the attached FIG. 10).

Each structural module 11 includes, in exemplifying and preferred, but not limiting, embodiments of the invention, 64 photovoltaic receivers 16, all connected in series each other, as shown in detail in the appended FIGS. 13-21.

In particular, the modular structure 11 with outer elongated dissipating elements 10 (FIGS. 13-18 attached) presents both at the front and at the back a transparent surface or glass 14, at the bottom 15, and the parabolic reflectors 13 are attached (preferably by gluing) inside the module 11, on the rear transparent surface 14.

Appended FIG. 22 illustrates a wiring harness between two photovoltaic receivers 16 adjacent each other.

The electric connection is made with a copper rigid and naked wire 30 (i.e. without insulation), or with a tinned conductive strip, always made of copper, welded to the ends 31 on the shaped elements 24, 25 of each photovoltaic receiver 16 and suspended at a distance of few millimetres (5-10 mm) from the alumina substrate 22 and the aluminium elongated element 10, 12, so that the electrical insulation consists of air.

This solution allows to carry out the low cost connection between the receivers 16, with the maximum guarantee of durability and minimal electrical resistance, since the naked wire 30 (no plastic insulations cover it) is not exposed to possible damage due to conditions of misalignment of the module 11.

Indeed, even if the structural module 11 is misaligned with respect to the sun, the light concentrated beam RST which may possibly affect the copper wire 30 (with intensity of several tens of W/cm2) does not cause any problem; contrary, if plastic insulations were used, the light concentrated beam RST could damage the insulation.

The use of a Teflon insulation or other special materials could be an alternative methodology to the plastic insulation, although in such cases the cost would be greater than the naked copper solution.

Therefore, all the photovoltaic receivers 16 of the structural module 11 are connected in series according to the connection diagram shown in the attached FIG. 23 and the 64 photovoltaic cells CS (preferably distributed according to an 8×8 matrix) are connected in series.

Furthermore, as already described, each solar cell CS is connected in parallel with a bypass diode 23, which avoids overheating and consequent damage of the single solar cell CS, in case the cell CS itself is in shading conditions and simultaneously, the other cells CS are in full radiation conditions.

The series connection is optimal for the performances of the module 11, because the cells CS are crossed by the same current, while the voltage of the cells CS sum each other providing a high output voltage V convenient for the conversion necessary for the introduction into the public power supply.

For example, using solar cells CS of the III-V type, each of which presents an output voltage (at maximum power conditions) of about 2.3 Volts, the output voltage V from the module 11 is 147 Volts (2.3×64), while the output current of the module 11, equal to the current generated by each cell CS is, in conditions of maximum power, equal to about 1 Ampere.

A standard version of the structural module 11 provides the output of the two terminal cables C1, C2 from the frame of the module 11 through two simple fairleads.

The photovoltaic generator 34, according to the invention, consists of several structural modules 11, connected each other in series and in parallel and connected with a solar tracker 33, as schematically shown in the attached FIG. 24.

The various modules 11 are connected so as to provide a direct current (DC) bus with two terminals C1, C2 connected with the input of a DC/AC converter, necessary to supply energy into the power supply.

For example, a 3 kW photovoltaic generator 34 may consist of a matrix (5×4) of 20 concentration photovoltaic modules 11 (each made as in the embodiments illustrated in FIG. 1 or 2), mounted on a single wing of the type marked with 32 ion the enclosed FIG. 24.

Similarly, a 4.5 kW photovoltaic generator 34 may consist of a matrix (6×5) of 30 photovoltaic modules 11 of 150 W each.

The structural modules 11 are connected in series and in parallel according to the scheme shown in the attached FIG. 25, which refers to the case of a 3 kW photovoltaic generator, consisting of 20 modules 11 of 150 W each and output voltage V, at the terminals C1, C2, of about 300 Volts.

The attached FIG. 26 shows the electric diagram of a module DC/DC converter, of the “boost interleaved” type, at three phase, which is used optionally in a illustrative and preferred, but not limiting, embodiment of the photovoltaic module 11 and is applied to the module 11 in a sealed box of small dimensions, mounted outside the module 11 itself and connected with the cells CS. In this solution the connection of the modules 11 does not occur as in the arrangement shown in the appended FIG. 25.

Terminals C1 and C2 of FIG. 23 (i.e. the output terminals of the single module 11) are connected, respectively, with the inputs 11, 12 of the converter, which is governed by the controller M, which, in turn, generates the control signals of the three MOSFET Q1, Q2 and Q3 and adjusts the power absorbed by the photovoltaic module 11 trying to maximize the intensity thereof in every moment of operation (through the so-called MPPT, “Maximum Power Point Tracking”, function).

The operation is that one of the “interleaved boost”, consisting of three switching converters of the “boost” type, such as those ones comprising the components (Q1, L1, D1, C1), (Q2, L2, D2, C2) and (Q3, L3 D3, C3), all connected in parallel each other and controlled in temporal alternate and equally distributed in the axis of time phases; this technique allows, among the other things, to minimize the “ripple” at the frequency of switching of the input current at the terminal 11 and the operation of the photovoltaic cells CS is optimal, since the peak of intensity of the current itself are reduced.

The controller M contains a microcontroller and proper signal conditioning circuits, so that from the line VIN the aforesaid controller M gets the supply voltage for its own operation and simultaneously measures the input voltage, that is the voltage of the series of solar cells CS constituting the module 11.

The lines IIN are connected to the current sensor SC, which measures the current at the input of the converter, while G1, G2 and G3 are the control signals of the GATES of the MOSFET, respectively Q1, Q2, Q3, out of phase of 120° each other and the line VOUT allows the measure of the output voltage V1 of the module 11.

In practice, once the voltage of the solar cells CS exceeds a minimum or start-up value, for example, greater than the half of the nominal value (such as 75 Volts, in case a module 11 with a nominal voltage of about 150 Volts is used), the converter starts operating, adjusting the output voltage V1 to a prefixed value of 400 Volts (always greater than the maximum voltage of the solar cells CS):

The converter measures in every moment the input current on the lines IIN and the input voltage on the line VIN and calculates the input power as product between voltage and current, while the control algorithm generated by the controller M, keeping the output voltage V1 strictly to the set value of 400 Volts, continuously changes the control “duty-cycle” of the GATES G1, G2 and G3, in order to maximize in every moment the input power.

Thus, the converter behaves at the output as a generator which provides output in every moment, at the voltage of 400 Volts, the maximum current available and usable by the electrical load connected downstream the converter.

The output of the converter is connected in parallel with the outputs of other converters of other modules, as shown in the FIG. 27 attached, and can also be connected with the input of a DC/AC converter (inverter) suitable to the connection with the public power supply, in order to inject into the power supply the produced energy.

The advantage offered by the use of the converter of the appended FIG. 26 is basically to make independent the various photovoltaic modules 11, which constitute each photovoltaic generator 34, consisting of several modules 11; in fact, each converter, and therefore, each module 11 is able to provide the maximum amount of power available, in any moment, from every single module 11.

In case of high-concentration modules 11 each equipped with the converter of the attached FIG. 26, the connection among the modules 11, which form the photovoltaic generator 34 (for example, of 3 kW), is shown in the enclosed FIG. 27 (that is all in parallel each other).

Finally, the photovoltaic generator 34 may be associated with an inverter 35 with circuit breaker and completed with a system of control of the engines of the solar tracker 33; the inverter 35 incorporates the “booster” when the generator 34 is integrated into an energy management and/or home automation system (as shown in the attached FIG. 28).

In this case, the inverter 35 provides a peak power of 3.3 kW, an operating range of 3 kWh and a series of back-up batteries 36 for the emergency operation, in case of absence of the supply from the public power supply 39.

The inverter 35 is connected by radio (with radio waves communication of the FH-DSSS type) with a counter 37 of the energy supplied into the home power supply 41, a counter 38 of the energy consumed and any intelligent switch 40 (for the operation in island).

It is also provided the use of a control unit 44 of domestic control, suitable to manage in complete way the photovoltaic system and the safety system, which communicates wirelessly, via FH-DSSS and/or GSM, with bidirectional radio communication in the band 2,400-2,486 GHz, with a series of sensors and/or actuators for the home automation, safety and anti-theft, self-powered by non-rechargeable batteries, such as passive infrared detectors, perimetrical detectors, smoke detectors with emergency light, gas detectors, flooding detectors, portable remote controls, radio keyboards, sirens for outside and intelligent, radio controlled, socket 42 (for external use or built-in) for the management of the relative loads 43.

It is also provided a mobile terminal 45 with “touch screen” interface, with functions of telephone, remote assistance, electricity, lighting, safety and home automation command and control, as well as with functions of monitoring and configuration of the photovoltaic system and energy, lighting plant (lights on/off, etc.) and other automatisms, such as garage door openers, door openers, anti-thefts, etc., management.

All the devices mentioned are provided with FH-DSSS radio communication at 2.4 GHz and are able to reciprocally exchange messages in real time obtaining functions of automation and, in particular, management of the energy flows of electrical type, beyond the normal functions of safety management and comfort automation.

In particular, the operation of the “booster” inverter 35, the intelligent sockets 42 and the intelligent switch 40 is as follows.

The “booster” inverter 35 normally keeps the battery 36 charged by using the energy coming from the photovoltaic generator 34 or from the public power supply 39, while the intelligent switch 40 incorporates an appropriate potentiometer of the net electrical power exchanged with the public power supply 39.

In all the electrical systems connected with the public supply, in case the power drawn from the public power supply 39 exceeds a maximum supply limit defined by the provider of electricity and adjusted by an automatic breakdown device (not shown in the figures attached), the automatic disconnection of the electrical system from the public power supply 39 occurs.

The intelligent switch 40, therefore, by detecting a power absorption greater than the maximum limit available from the provider, immediately signals, through the built-in FH-DSSS radio communicator, this information to the “booster” inverter 35.

The latter, by detecting such a condition, activates itself supplying to the home power supply 41 the lacking power by drawing energy from the battery 36.

It is obvious that in case of presence of the sun the energy possibly required is drawn directly from the sun, and in this case, the operation is that one of a conventional photovoltaic system connected with the public power supply, in which the energy balance is, moment by moment, determined by the fact that the total power of the users is equal to the sum of the public power supply and the photovoltaic system.

When, for example, due to a sky cloudiness, there is a significant decrease of the amount of power generated by the photovoltaic system, the “booster” inverter 35 is able to keep operating the electrical loads of the house which exceed the availability of power of the public power supply 39, thanks to energy stored in the batteries pack 36.

This mechanism allows to get advantages both for the user (who may use electrical loads oversized with respect to the supply power of the public power supply 39, without incurring the cost of an oversized supply contract) and for the provider of the public power supply 39 (which sees reduced the energy flows in his power supply).

Indeed, the system of energy storage varied out by the “booster” inverter 35 allows to stabilize the availability of energy of the photovoltaic system for a not only immediate, but also mediated through time, direct local use. Another possible function concerns the intelligent sockets 42, which can be coordinated with the “booster” inverter 35 and the loads 43, which, for example, may consist of household appliances such as a washing machine.

The user has only to prepare the household appliance for the operation (for example he loads the washing machine with the white goods to be washed), after which the intelligent socket 42 connected with it adjusts the operation thereof depending on the electricity available from the renewable source constituted by the photovoltaic system.

In this way, the washing machine of the example is turned on by intelligent socket 42 only during daylight hours when energy is available from the sun, once again reducing energy flows crossing the public electric network.

The benefit for the electrical system is evident: the photovoltaic energy is directly used in the most efficient way, near the generator which produces it and without burdening the public electric network 39, therefore deriving from it as biggest advantage as possible.

For the user the evident advantage is represented by the fact that the appliance, even if at high power consumption, since it is managed by the intelligent socket 42, does not lower the availability of power in the home power supply 41, as it is powered at all times from the sun; therefore, the user can draw energy for other aims, without worrying about the automatic breakdown due to the surplus of available power requested to the provider.

The third possible innovative function, thanks to the “booster” inverter 35 and the intelligent switch 40, relates to the management of the blackout situations of the public electricity network 39.

Indeed, the intelligent switch 40, detecting the condition of absence of energy on the public power supply 39, sections safely (with electromechanical redundant device) the home power supply 41 from the public network 39 and, simultaneously, being equipped with a small back-up battery for its own operation even in absence of supply of the public power supply 39, communicates by radio to the “booster” inverter 35 to activate such as main generator (and no more as synchronous generator with the public power supply 39), in order to supply energy in the local home power supply 41 according to a so-called “island” operation.

Even in this case the smart sockets 42 cooperate with the operation of the system, since, according to the available energy from the battery 36 and/or the photovoltaic generator 34 and according to the emergency strategies defined by the user, only part of the intelligent sockets 42 will be activated, so as to assure the availability of energy to the “island” system, without overloading the “booster” 35 and in nay case causing, according to predefined requirements, the best compromise between the “island” running time (determined by the length of the blackout and the amount of energy stored in the battery 36) and the amount of power required by the electrical loads 43.

From the description made, the features of the high-concentration photovoltaic generating module, which is the object of the present invention, are clear, as well as the resulting benefits.

It is, finally, clear that many variations can be made to the photovoltaic module in question, without for this reason going out of the novelty principles inherent to the inventive idea, as it is clear that, in the practical implementation of the invention, materials, shapes and sizes of the details illustrated may be any, according to needs, and the same may be replaced with others technically equivalent.

1. A high-concentration single-reflection photovoltaic generating module (11) comprising:
a plurality of solar radiation (RS) concentrating devices, which include relative parabolic reflectors (13) mounted on a base support (15), which is placed within said module (11);
at least one transparent front surface (14), through which the solar radiation (SR) is transmitted;
a plurality of photovoltaic receivers (16), which are mounted within the module (11) and which are series-connected one with each other,
wherein said photovoltaic receivers (16) are fixed on elongated elements (10, 12) which are made of conductive material and which are able to dissipate heat, at least one portion of each elongated element (10, 12) being located inside the module (11), said elongated elements (10, 12) being also able to accommodate at least one photovoltaic cell (CS),
characterized in that said module (11) has a reticular structure, comprising said elongated elements (10, 12), which are parallel to each other, and a plurality of flow tubes (20), made of conductive material, each of said flow tube (20) being perpendicular to said elongated elements (10, 12) and being connected, with low thermal resistance, on one side with an internal portion (19) of each elongated element (12) and on the other side with said base support (15), so as to facilitate a heat exchange with the air inside the module (11) and to transport the heat towards said base support (15), which is therefore thermally connected to said internal portions (19) of each elongated element (12).

2. Module (11) as claimed in claim 1, characterized by the fact that each parabolic reflector (13) concentrates the solar radiation (SR), which is transmitted through said transparent surface (14), at an inlet (BI) of a mixing optical system (OS) as an incoming light flow (RTD).

3. Module (11) as claimed in claim 2, characterized by the fact that said optical system (OS) is made in the shape of a truncated pyramid, whose side walls are shaped so as to reflect and mix said incoming light flow (RTD).

4. Module (11) as claimed in claim 1, characterized by the fact that said parabolic reflectors (13) are made from a sheet metal, which is stamped and mirror-polished, or from plastic supports obtained from mirror-polished and metallized moulds, or from printed and metallized glass.

5. (canceled)

6. Module (11) as claimed in 1, characterized by the fact that each photovoltaic receiver (16) includes:
a base plate (22), made with conductive tracks, with high thermal conductibility and high electrical insulation,
said at least one photovoltaic cell (CS),
at least one by-pass diode (23), which is parallel-connected to said least one photovoltaic cell (CS),
at least two shaped elements (24, 25), made of conductive material, to which at least one wire (30) is connected for electrically connecting in series at least two photovoltaic receivers (16) and at least two respective photovoltaic cells (CS).

7. Module (11) as claimed in claim 6, characterized by the fact that said by-pass diode (23) is positioned below at least one (25) of said shaped elements (24, 25), in order to be protected from the incident solar radiation (RTD).

8. Module (11) as claimed in claim 7, characterized by the fact that said at least one photovoltaic cell (CS) is mounted and electrically and thermally connected to said base plate (22).

9. Module (11) as claimed in claim 1, characterized by the fact that at least one transparent rear surface (14) is placed at said base support (15) and said parabolic reflectors (13) are fixed on said transparent rear surface (14), within the module (11)

10. Module (11) as claimed in claim 6, characterized by the fact that said at least one wire (30) is without insulation and is welded at the ends (31) of said shaped elements (24, 25) of each photovoltaic receiver (16) and suspended at a fixed distance from said base plate (22).

11. Module (11) as claimed in claim 1, characterized by the fact that said module (11) is connected to a 3-phases DC/DC converter, in particular to a “boost interleaved” converter, which is controlled by a controller (M), which regulates the power drawn by the module (11), in order to maximize the power intensity and the maximum current of each module (11) which are available and usable by the electrical load connected downstream the converter, at any given time of operation.

12. Module (11) as claimed in claim 11, characterized by the fact that the output of said converter is electrically connected in parallel to the outputs of other converters of other modules (11).

13. Module (11) as claimed in claim 11, characterized by the fact that the output of said converter is electrically connected to the input of an inverter or DC/AC converter, which is connected to a public power supply (39).

14. Photovoltaic generator (34) comprising a plurality of high-concentration single-reflection photovoltaic generating modules (11) as claimed in claim 1, characterized by the fact that said modules (11) are electrically connected in series and/or in parallel one with each other and are connected to at least one solar follower (33).

15. Photovoltaic generator (34) as claimed in claim 14, characterized by the fact that said modules (11) are mechanically connected to a single support (32) and are electrically connected one with each other, so as to provide an output DC bus with its terminals (C1, C2) connected to the input of a DC/AC converter, which is able to inject into the public power supply (39) the electricity supplied by the generator.

16. Photovoltaic generator (34) as claimed in claim 14, characterized by the fact that said generator is connected to at least one inverter (35) with circuit breaker and control system for engines of said solar follower (33).

17. Photovoltaic generator (34) as claimed in claim 16, characterized by the fact that said generator (34) is integrated in a management system for electricity and/or home automation and said inverter (35) is connected, via radio, with a first counter (37) of the electricity supplied from said generator (34) and injected into a home power supply (41) and/or with a second counter (38) of the electricity which is consumed and/or with an intelligent switch (40).

18. Photovoltaic generator (34) as claimed in claim 17, characterized by the fact that a control unit (44) controls said generator (34) and the photovoltaic system by communicating, via radio, with a plurality of sensors and/or actuators for home automation, for security and for anti-intrusion, such as passive infrared detectors, perimeter sensors, smoke detectors with emergency light, gas detectors, flood detectors, remote controls, portable radio keyboards, outdoor sirens, intelligent sockets (42) which manage relative electric loads (43) and/or mobile terminals (45), such as “touch screen” terminals, with a telephone, alarm, command and control functions related to the photovoltaic system and/or to an electrical plant, a light system, a security system, a home automation system and/or to other automatic devices, such as open-gate devices, open doors devices, alarms, etc.

19. Photovoltaic generator (34) as claimed in claim 18 characterized by the fact that an intelligent switch (40) measures the electrical power which is exchanged between said electric loads (43) and the public power supply (39) and controls the disconnection of said electrical loads (43) when the power drawn from said public power supply (39) exceeds a prefixed upper value, indicating the excess of said value, via radio, to said inverter (35) so that said inverter (35) injects into the public power supply (39) the missing power by drawing energy from a battery (36) or from said photovoltaic generator (34).

20. Photovoltaic generator (34) as claimed in claim 18, characterized by the fact that said intelligent sockets (42) control the operation of the relative electric loads (43) according to the electricity which is available from said photovoltaic generator (34).

21. Photovoltaic generator (34) as claimed in claim 18, characterized by the fact that said intelligent switch (40) detects a blackout of the public power supply (39) and disconnects the home power supply (41) from said public power supply (39) and controls, via radio, said inverter (35) in order to activate it as a main generator of electricity, said inverter (35) being able to activate at least some of said intelligent sockets (42) of the home power supply (41), so as to ensure the availability of electricity to said sockets (42).
